(19) United States
(12) Patent Application Publication
(10) Pub. No.: US 2025/0370863 A1
(43) Pub. Date: Dec. 4, 2025

(54) SELF-REPAIR OF ANALOG CIRCUITS USING REDUNDANCY

(71) Applicant: Cirrus Logic International Semiconductor Ltd., Edinburgh (GB)

(72) Inventors: Eric IVERSON, Austin, TX (US); Kathryn R. HOLLAND, Cedar Park, TX (US); John L. MELANSON, Austin, TX (US); Suman BANERJEE, Austin, TX (US)

(73) Assignee: Cirrus Logic International Semiconductor Ltd., Edinburgh (GB)

(21) Appl. No.: 18/785,230

(22) Filed: Jul. 26, 2024

Related U.S. Application Data
(60) Provisional application No. 63/654,510, filed on May 31, 2024.

(51) Int. Cl. G06F 11/10; G06F 11/16

(52) U.S. Cl. CPC G06F 11/1052; G06F 11/1612

(57) ABSTRACT

A system may include a set of redundant circuit elements, detection circuitry configured to detect a respective error for each circuit element of the set of redundant circuit elements, and control circuitry configured to selectively enable and disable one or more of the set of redundant circuit elements for functional use in a circuit based on the respective errors.

### RELATED APPLICATIONS

The present disclosure claims priority to U.S. Provisional Patent Application Ser. No. 63/654,510, filed May 31, 2024, which is incorporated by reference herein in its entirety.

### FIELD OF DISCLOSURE

The present disclosure relates in general to methods, apparatuses, and implementations concerning or relating to analog integrated circuit design. Applications include, but are not limited to, those concerning the design of low-noise integrated circuits sensitive to random telegraph noise (RTN), flicker noise, shot noise, or offset, or other errors.

### BACKGROUND

There are several types of error that may be present in individual circuit elements such as metal-oxide-silicon field-effect transistors (MOSFETs), resistors, or bipolar junction transistors as a result of process variation in integrated circuit manufacturing. These error sources may include, among other things, random telegraph noise (RTN), flicker noise, shot noise, and static offset. RTN in MOSFETs is particularly problematic owing to its presentation as a low-probability, catastrophically large, strongly temperature-dependent noise source that makes prediction and screening challenging.

RTN (also known as burst noise, popcorn noise, impulse noise, and bi-stable noise) is a class of low-frequency noise resulting from manufacturing process defects near the channel region of FETs. It is characterized by discrete, large amplitude shifts in drain current corresponding to the capture and emission of single charge carriers within the channel. RTN occurs in all MOSFETs and is not completely escapable through changes in device size or bias. Any noise-critical signal path may have yield loss caused by RTN, including oscillators, amplifiers, bias circuitry, and bandgap voltage generators. When multiple instances of the same transistor exist in a circuit, it is highly unlikely to observe more than a single device with catastrophically large RTN. FIG. 1 illustrates example output current waveforms from sixteen (16) identical transistors, with one transistor showing catastrophic RTN amplitude while the others show typical low-frequency noise amplitude, as is known in the art.

Existing approaches to mitigating RTN include signal chopping to eliminate low-frequency noise from amplifiers and switched biasing, an example of which is disclosed by Klumperink, Eric et al., “Reduction of 1/f Noise by Switched Biasing: an Overview,” 16th Workshop on Circuits, Systems and Signal Processing, ProRISC 25 Nov. 2005.

### SUMMARY

In accordance with the teachings of the present disclosure, one or more disadvantages and problems associated with errors in analog circuits may be reduced or eliminated.

In accordance with embodiments of the present disclosure, a system may include a set of redundant circuit elements, detection circuitry configured to detect a respective error for each circuit element of the set of redundant circuit elements, and control circuitry configured to selectively enable and disable one or more of the set of redundant circuit elements for functional use in a circuit based on the respective errors.

In accordance with these and other embodiments of the present disclosure, a method may include detecting a respective error for each circuit element of a set of redundant circuit elements and selectively enabling and disabling one or more of the set of redundant circuit elements for functional use in a circuit based on the respective errors.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates example output current waveforms from sixteen (16) identical transistors, with one transistor showing catastrophic RTN amplitude while the others show typical low-frequency noise amplitude, as is known in the art;

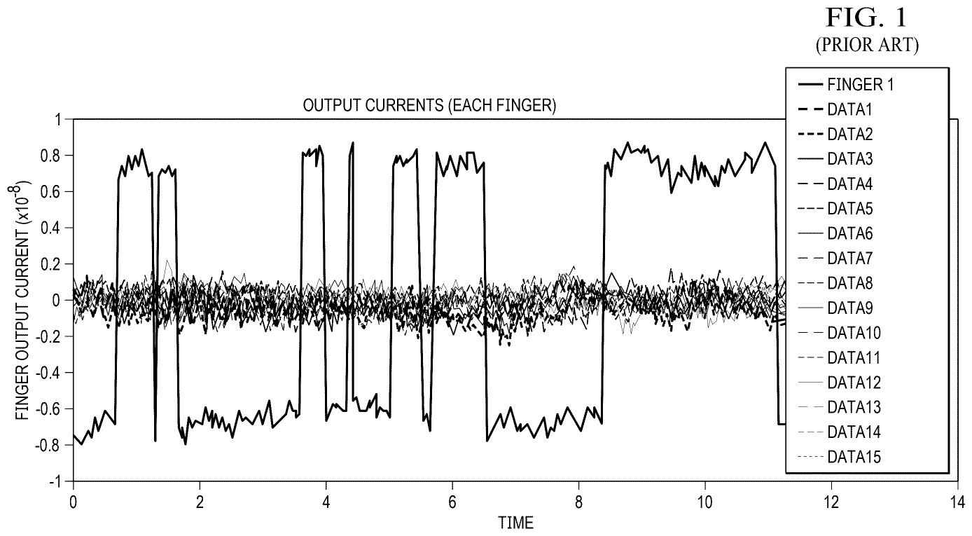

FIG. 2 illustrates a block diagram of a system for self-repair of analog circuits using redundancy, in accordance with embodiments of the present disclosure;

FIG. 3 illustrates a flow chart for an example method for self-repair of a circuit having an array of redundant at-risk circuit elements, in accordance with embodiments of the present disclosure;

FIG. 4 illustrates a block diagram of a system that may be used to implement the system shown in FIG. 2, in accordance with embodiments of the present disclosure;

FIG. 5 illustrates a block diagram of another system that may be used to implement the system shown in FIG. 2, in accordance with embodiments of the present disclosure;

FIG. 6 illustrates a block diagram of yet another system that may be used to implement the system shown in FIG. 2, in accordance with embodiments of the present disclosure;

FIG. 7 illustrates a block diagram of yet another system that may be used to implement the system shown in FIG. 2, in accordance with embodiments of the present disclosure;

FIG. 8 illustrates selected components of an error detector that may be used in connection with a redundant array of singular elements such as that shown in FIG. 7, in accordance with embodiments of the present disclosure;

FIG. 9 illustrates selected components of another error detector that may be used in connection with a redundant array of singular elements such as that shown in FIG. 7, in accordance with embodiments of the present disclosure;

FIG. 10 illustrates a circuit diagram of an example system that uses a redundant transistor array to implement a low-noise differential pair, in accordance with embodiments of the present disclosure;

FIG. 11 illustrates a block diagram of an example system in which a single error detector and a single control circuit may be used for a plurality of sub-blocks, in accordance with embodiments of the present disclosure; and

FIG. 12 illustrates a block diagram of an example system employing the same concept of analog redundancy, in accordance with embodiments of the present disclosure.

### DETAILED DESCRIPTION

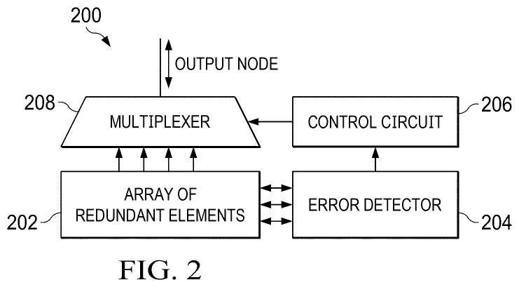

FIG. 2 illustrates a block diagram of a system 200 for self-repair of analog circuits using redundancy, in accordance with embodiments of the present disclosure. As shown in FIG. 2, system 200 may include an array 202 of redundant at-risk circuit elements, an error detector circuit 204, a control circuit 206, and a multiplexer 208.

Array 202 may include a plurality of any suitable circuit elements, wherein the constituent circuit elements may be identical or highly similar to one another. Examples of such circuit elements are described in greater detail below.

Error detector circuit 204 may comprise any suitable system, device, or apparatus configured to detect error (e.g., noise) within array 202 of redundant at-risk circuit elements, and identify which circuit element(s) within array 202 are associated with the error. As used herein, “error” may refer to all error sources associated with a circuit element, including without limitation RTN, shot noise, flicker noise, and/or static offset.

Control circuit 206 may comprise any suitable system, device, or apparatus configured to, based on the circuit element(s) within array 202 identified to have error, generate one or more control signals, which may be referred to as “select bits” for controlling multiplexer 208. In some embodiments, the functionality of error detector circuit 204 and control circuit 206 may be combined into a single circuit.

Multiplexer 208 may comprise any suitable system, device, or apparatus configured to, based on the one or more control signals generated by control circuit 206, selectively enable and disable circuit elements within array 202. Thus, acting together in concert, error detector circuit 204, control circuit 206, and multiplexer 208 may identify circuit element(s) within array 202 that are associated with error, disable such circuit element(s), and enable one or more circuit elements of array 202 free from error. By “enabling” a circuit element, multiplexer 208 may cause such circuit element to be electrically coupled to another electrical node (e.g., to an output node, to an input node, to another circuit, etc.) and by “disabling” a circuit element, multiplexer 208 may cause such circuit element to be electrically decoupled from another electrical node (e.g., from an output node, from an input node, from another circuit, etc.).

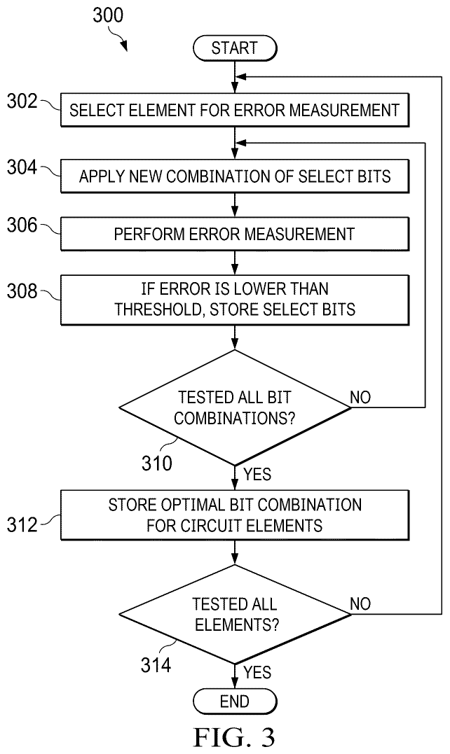

FIG. 3 illustrates a flow chart for an example method 300 for self-repair of a circuit having an array of redundant at-risk circuit elements, in accordance with embodiments of the present disclosure. According to certain embodiments, method 300 may begin at step 302. As noted above, teachings of the present disclosure may be implemented in a variety of configurations of system 200 as shown in FIG. 2. As such, the preferred initialization point for method 300 and the order of the steps comprising method 300 may depend on the implementation chosen.

At step 302, control circuit 206 may select a circuit element of array 202 for measurement of error. At step 304, control circuit 206 may apply a new combination of select bits to multiplexer 208 associated with the selected element. At step 306, error detector 204 may measure an error in response to the combination of select bits. At step 308, if the measured error is lower than a threshold error level, control circuit 206 may store the combination of select bits.

At step 310, control circuit 206 may determine if all bit combinations associated with the selected circuit element have been tested. If all bit combinations have been tested, method 300 may proceed to step 312. Otherwise, method 300 may proceed again to step 304.

At step 312, control circuit 206 may store the optimal bit combination for the selected circuit element. At step 314, control circuit 206 may determine if all circuit elements of array 202 have been tested. If all circuit elements of array 202 have been tested, method 300 may end. Otherwise, method 300 may proceed again to step 302.

Accordingly, using method 300, system 200 may determine if error is detected in a circuit element in the redundant array, and if such error is detected, then control circuit 206 may control multiplexer 208 to disable such circuit element in favor of another circuit element of array 202 which may be a redundant copy of the disabled circuit element.

Although FIG. 3 discloses a particular number of steps to be taken with respect to method 300, it may be executed with greater or fewer steps than those depicted in FIG. 3. In addition, although FIG. 3 discloses a certain order of steps to be taken with respect to method 300, the steps comprising method 300 may be completed in any suitable order. Method 300 may be implemented using system 200, components thereof, or any other suitable system operable to implement method 300.

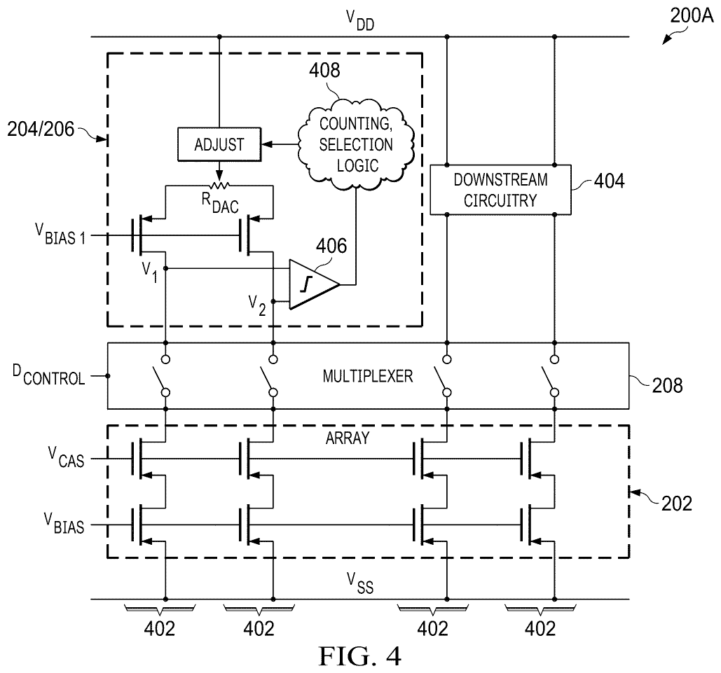

FIG. 4 illustrates a block diagram of a system 200A for self-repair of analog circuits using redundancy, in accordance with embodiments of the present disclosure. In some embodiments, system 200A may be used to implement system 200 of FIG. 2. As shown in FIG. 4, in system 200A, array 202 may be implemented with a plurality of MOSFET current mirrors 402. Further in system 200A, multiplexer 208 may selectively couple output nodes of current mirrors 402 to either of error detector 204 and control circuitry 206 (which is shown as combined together into a single circuit in FIG. 4) or to downstream circuitry 404, in which case output nodes of the selected current mirrors 402 may be used functionally by such downstream circuitry 404 (e.g., biasing of opamps or reference circuits, controlling signal currents, etc.).

As further shown in FIG. 4, error detector 204/control circuitry 206 of system 200A may include a comparator 406 that may monitor instantaneous voltages (e.g., labeled as V₁ and V₂ in FIG. 4) at selected output nodes of current mirrors 402, which may serve as test outputs for error detection. The output of the comparator may drive into counting and selection logic 408 which may perform at least two key functions: 1) driving an instantaneous (or clocked at high speed) digital-to-analog (DAC) code to control a variable resistance R_{DAC} within error detector 204/control circuit 206, which may serve to balance the voltages V₁ and V₂; and 2) monitoring the statistics of the DAC code such that error, for example catastrophic RTN noise, may be identified according to the distribution of the DAC code over time. Accordingly, comparator 406 and R_{DAC}-balanced current sources may comprise an implementation of error detector 204 and control circuit 206 shown in FIG. 2 and described above.

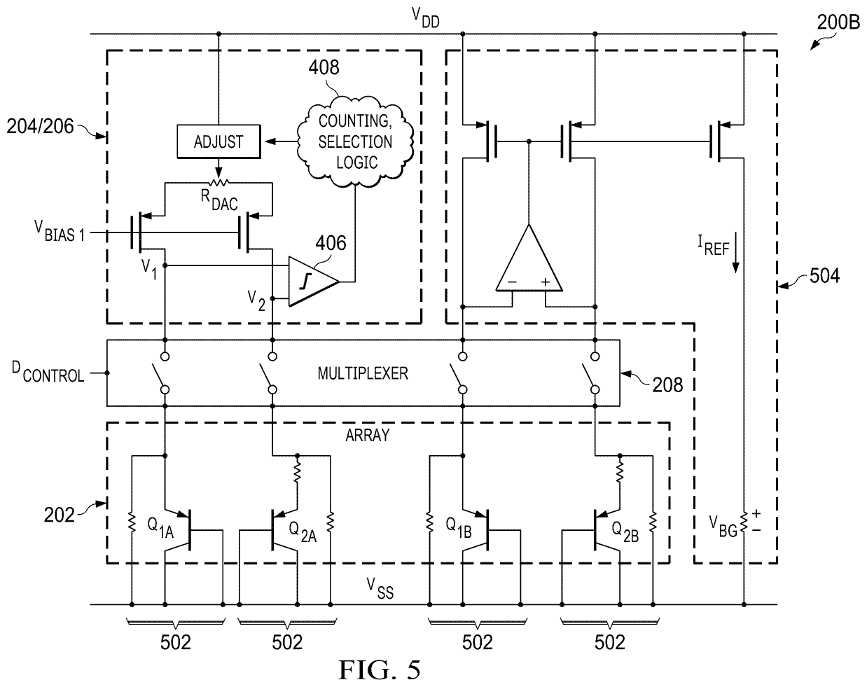

FIG. 5 illustrates a block diagram of a system 200B for self-repair of analog circuits using redundancy, in accordance with embodiments of the present disclosure. In some embodiments, system 200B may be used to implement system 200 of FIG. 2. System 200B shown in FIG. 5 may be similar in many respects to system 200A of FIG. 4, and thus only certain differences between system 200A and 200B are described herein.

In particular, as shown in FIG. 5, the redundant circuit elements of array 202 of system 200B may each include a bandgap core circuit 502 having a combination of bipolar junction transistors (BJTs) and resistors. Further, system 200B may include downstream circuit 504, implemented as a current-controlling operational amplifier that sets a bandgap output current I_{REF}, in lieu of downstream circuit 404.

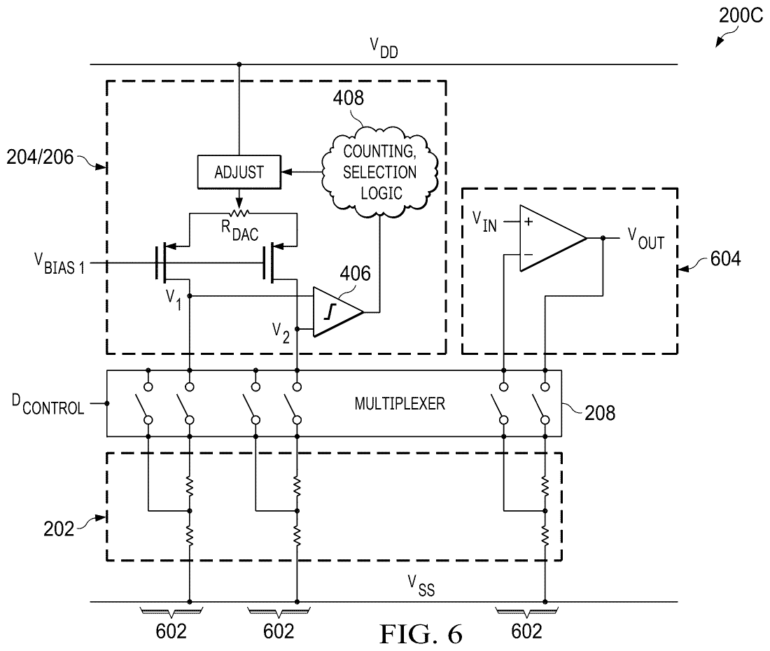

FIG. 6 illustrates a block diagram of a system 200C for self-repair of analog circuits using redundancy, in accordance with embodiments of the present disclosure. In some embodiments, system 200C may be used to implement system 200 of FIG. 2. System 200C shown in FIG. 6 may be similar in many respects to system 200A of FIG. 4, and thus only certain differences between system 200A and 200C are described herein.

In particular, as shown in FIG. 6, the redundant circuit elements of array 202 of system 200C may each include a resistor-divider circuit 602, which may need noise control for low-noise applications such as implementing a gain setting in an opamp-based gain buffer circuits. Further, system 200C may include downstream circuit 604, implemented as an operational amplifier configured for a non-inverting gain of an input voltage V_{IN} to generate an output voltage V_{OUT}, in lieu of downstream circuit 404.

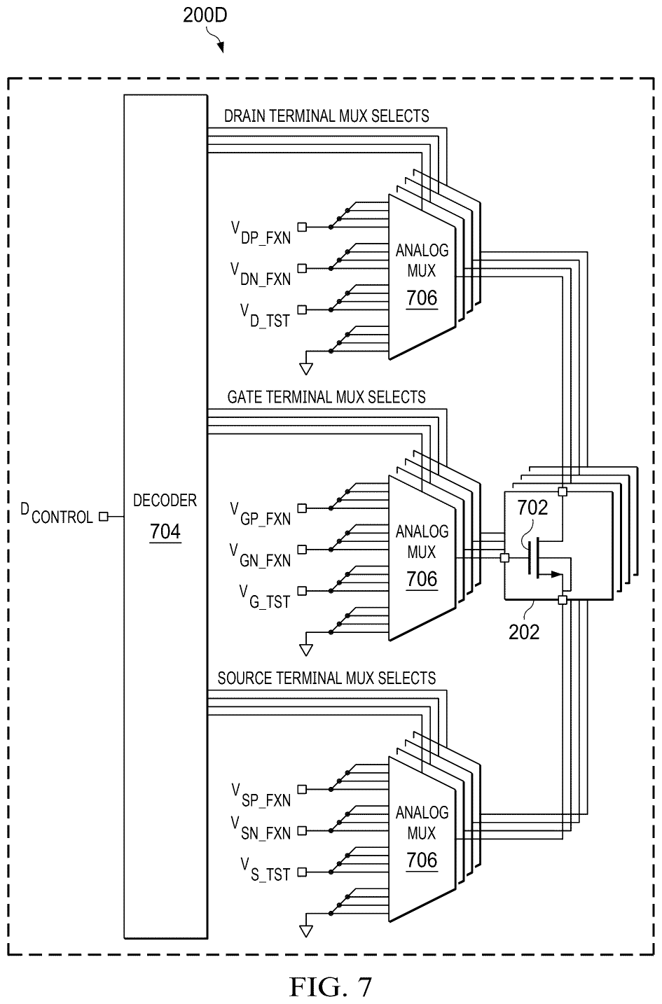

In some embodiments, array 202 may be implemented as a redundant array of individual transistors (e.g., MOSFETs or BJTs), in which some or all of the terminals are multiplexed for the purposes of error detection and subsequent selection. To that end, FIG. 7 illustrates selected components of a system 200D for self-repair of analog circuits using redundancy, in accordance with embodiments of the present disclosure. In some embodiments, system 200D may be used to implement system 200 of FIG. 2.

As shown in FIG. 7, array 202 may be implemented as a plurality of transistors 702, and multiplexer 208 may be implemented as a decoder 704 configured to generate respective control signals (e.g., multiplexer select signals) for analog multiplexers 706 each associated with a respective terminal for transistors 702. For purposes of clarity and exposition, certain portions (e.g., error detector 204/control circuit 206) of system 200D are not shown in FIG. 7.

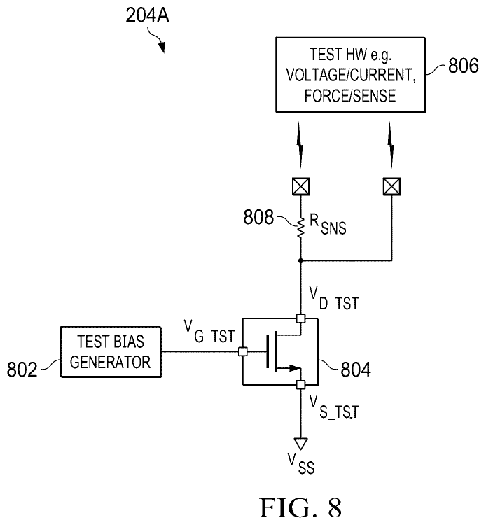

However, FIG. 8 illustrates selected components of an error detector 204A (which may implement error detector 202A of FIG. 2) that may be used in connection with redundant array 202 of singular elements such as that shown in FIG. 7, in accordance with embodiments of the present disclosure. As shown in FIG. 8, a test bias generator 802 may apply a test bias to a gate terminal of the individual device 804 (e.g. a transistor) under test, a single device, or subset of devices from array 202 selected by control circuit 206. Test hardware 806 may detect the error, for example by analyzing a voltage or a current sensed by a sense resistor 808.

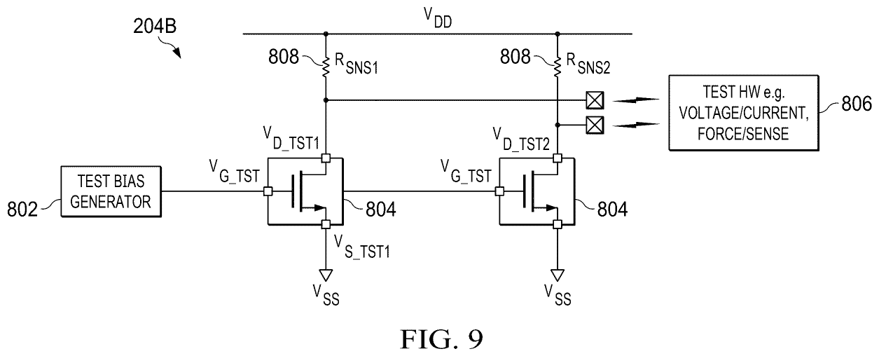

Similarly, FIG. 9 illustrates selected components of an error detector 204B (which may implement error detector 202A of FIG. 8) that may be used in connection with redundant array 202 of singular elements such as that shown in FIG. 7, in accordance with embodiments of the present disclosure. In particular, by adding additional complexity to error detector 204A shown in FIG. 8, error detector 204B may be extended to test two individual devices 804 of array 202 concurrently such that large-scale common mode signal may be cancelled with a differential sense for improved signal-to-noise ratio in the detected voltage, using differential sensing, for example.

Redundant transistor arrays such as those described above may be used as or in subcircuits such as, for example, differential pairs, current mirrors, operational amplifiers, current-controlled oscillators, bandgap voltage generators, etc. The systems and methods disclosed herein may employ any suitable level or degree of redundancy.

Such a redundant transistor array may facilitate detection of RTN on transistors or other circuit elements deemed to have high risk. High-risk circuit elements within a system may be identified by circuit simulation, and such identified high-risk circuit elements may include redundancy, as described herein. Selection of redundant elements with limited or no RTN may eliminate or severely reduce or solve yield loss due to extremely high noise outliers caused by RTN. Testing and selection of circuit elements from the redundant set may be performed at any suitable time or in response to any suitable stimulus, including at chip test, at power up, at change of temperature, passage of a predetermined period of time, user command, or continuously. Control circuit 206 described herein may be implemented off-chip or on-chip relative to the circuit element under test.

For embodiments targeted at reduction of RTN, error detector 204 may be implemented in any way that has sensitivity to RTN. For example, error detector 204 may include, but is not limited to, a peak-peak voltage detector, a root-mean-square (RMS) noise detector, an on-chip (analog-to-digital converter (ADC)), current- or voltage-to-frequency converter, and an edge detector. Error detector 204 may also incorporate detection algorithms making use of ADC output, via statistical analysis and/or machine learning techniques.

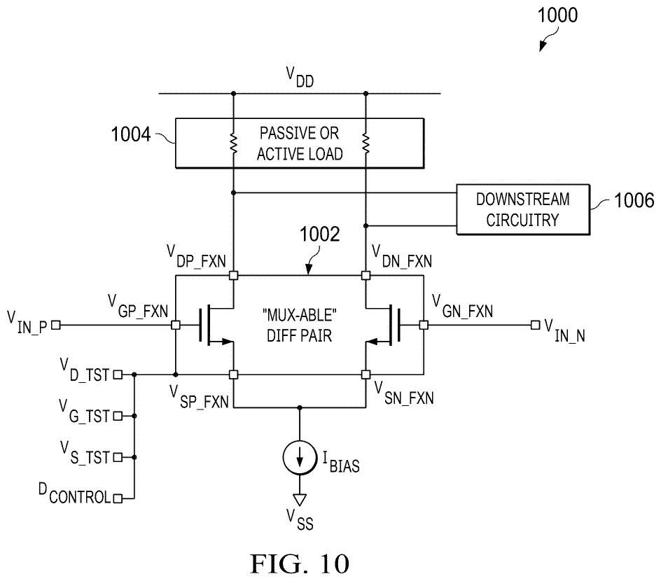

FIG. 10 illustrates a circuit diagram of an example system 1000 that uses a redundant transistor array to implement a differential pair 1002 with error self-repair (e.g., with a passive or active load 1004 and/or other downstream circuitry 1006), in accordance with embodiments of the present disclosure. Such a low-noise differential pair may be used as the input devices to an operational amplifier or comparator, for example.

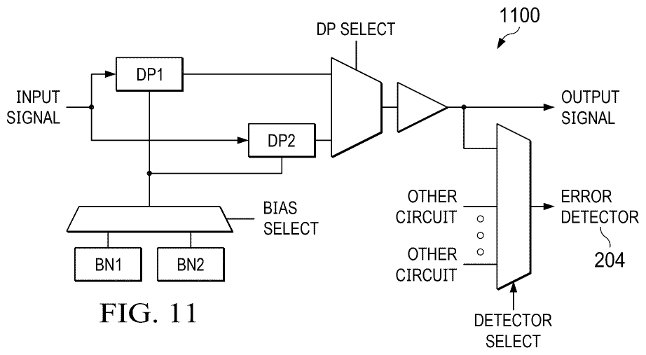

FIG. 11 illustrates a block diagram of an example system 1100 in which a single error detector 204 and single control circuit 206 may be used for a plurality of sub-blocks, in accordance with embodiments of the present disclosure. In system 1100, an amplifier may include a redundant differential pair (e.g., DP1, DP2) and a redundant bias network or current mirroring network (e.g., BN1, BN2). These redundant differential pairs DP1/DP2 and redundant bias networks/current mirroring networks BN1/BN2 may be multiplexed independently such that the optimal combination of DP and BN may be chosen to minimize error detected at an output of the amplifier. If multiple amplifiers are employing redundancy, a multiplexer may be used to swap error detector 204 between outputs. The selector bits “DP SELECT” and “BIAS SELECT” may be programmed (e.g., into on-chip memory) either during manufacturing or periodically over the lifetime of the part. In system 1100, error detector 204 may be implemented on-chip or off-chip relative to redundant differential pairs DP1/DP2 and/or redundant bias networks/current mirroring networks BN1/BN2.

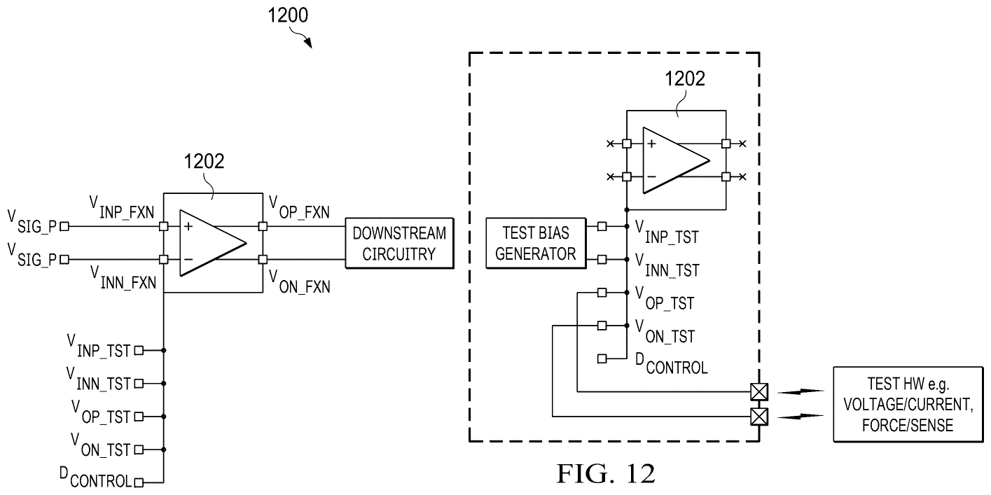

FIG. 12 illustrates a block diagram of an example system 1200 employing the same concept of analog redundancy described as above, wherein the redundant circuit element is a functional hierarchy of sub-circuits 1202. For example, the redundant circuit element 1202 may be an entire operational amplifier (e.g., as shown in FIG. 12), or a bandgap circuit.

Additionally, or alternatively, apparatuses, systems, and steps such as those described below may be incorporated into corresponding apparatuses or systems described above according to other embodiments of this disclosure:

For example, in some embodiments, systems and methods similar to those described above may be employed, wherein all elements of a redundant circuit array are measured, and the element(s) with lowest error are chosen for operation.

As another example, systems and methods similar to those described above may be employed, wherein redundant elements are characterized only in the event of a first element measuring unacceptable noise or error.

As an additional example, systems and methods similar to those described above may be employed, wherein a characterization process to select the lowest error elements in the redundant set may be triggered by a change in temperature, change in system state (e.g. active vs. standby mode, for instance), user request, a timer, and/or other similar stimulus.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
a set of redundant circuit elements;
detection circuitry configured to detect a respective error for each circuit element of the set of redundant circuit elements; and
control circuitry configured to selectively enable and disable one or more of the set of redundant circuit elements for functional use in a circuit based on the respective errors.

2. The system of claim 1, wherein the respective error for each circuit element comprises one or more of a random telegraph noise, flicker noise, shot noise, and offset associated with such circuit element.

3. The system of claim 1, wherein each circuit element comprises a transistor.

4. The system of claim 1, wherein each circuit element comprises a differential pair.

5. The system of claim 1, wherein each circuit element comprises a current mirror.

6. The system of claim 1, wherein each circuit element comprises a bipolar junction transistor pair.

7. The system of claim 1, wherein each circuit element comprises an operational amplifier.

8. The system of claim 1, further comprising biasing circuitry to provide a range of direct current biases under which to test the set of redundant circuit elements for their respective errors at a variety of operating points.

9. The system of claim 1, wherein the detection circuitry is configured to perform detection of the respective error for each circuit element of the set of redundant circuit elements in response to a stimulus.

10. The system of claim 9, wherein the stimulus comprises one of testing of the circuit, powering up of the circuit, a change of temperature associated with the circuit, a passage of a predetermined period of time, and a user command.

11. The system of claim 1, wherein the detection circuitry is on the same die as the set of redundant circuit elements.

12. The system of claim 1, wherein the control circuitry is on the same die as the set of redundant circuit elements.

13. The system of claim 1, further comprising logic on the same die as the set of redundant circuit elements to define a trigger to cause the detection circuitry to re-execute detection of the respective error for each circuit element of the set of redundant circuit elements and to cause the control circuitry to re-execute selectively enabling and disabling of one or more of the set of redundant circuit elements for functional use in the circuit based on the respective errors.

14. A method comprising:
detecting a respective error for each circuit element of a set of redundant circuit elements; and
selectively enabling and disabling one or more of the set of redundant circuit elements for functional use in a circuit based on the respective errors.

15. The method of claim 14, wherein the respective error for each circuit element comprises one or more of a random telegraph noise, flicker noise, shot noise, and offset associated with such circuit element.

16. The method of claim 14, wherein each circuit element comprises a transistor.

17. The method of claim 14, wherein each circuit element comprises a differential pair.

18. The method of claim 14, wherein each circuit element comprises a current mirror.

19. The method of claim 14, wherein each circuit element comprises a bipolar junction transistor pair.

20. The method of claim 14, wherein each circuit element comprises an operational amplifier.

21. The method of claim 14, further comprising providing a range of direct current biases under which to test the set of redundant circuit elements for their respective errors at a variety of operating points.

22. The method of claim 14, further comprising performing detection of the respective error for each circuit element of the set of redundant circuit elements in response to a stimulus.

23. The method of claim 22, wherein the stimulus comprises one of testing of the circuit, powering up of the circuit, a change of temperature associated with the circuit, and a passage of a predetermined period of time.

24. The method of claim 14, further comprising defining, with logic on the same die as the set of redundant circuit elements, a trigger to cause the detection circuitry to re-execute detection of the respective error for each circuit element of the set of redundant circuit elements and to cause the control circuitry to re-execute selectively enabling and disabling of one or more of the set of redundant circuit elements for functional use in the circuit based on the respective errors.
